(19) United States
(12) Patent Application Publication
(10) Pub. No.: US 2025/0210432 A1
(43) Pub. Date: Jun. 26, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chung-Chih YEN, Taichung City (TW); Chun-Chu LAI, Taichung City (TW)

(73) Assignee: SILICONWARE PRECISION INDUSTRIES CO., LTD., Taichung City (TW)

(21) Appl. No.: 18/816,303

(22) Filed: Aug. 27, 2024

(30) Foreign Application Priority Data
Dec. 22, 2023 (TW) 112150406

(51) Int. Cl. H01L 23/31; H01L 23/29; H01L 23/498

(52) U.S. Cl. CPC H01L 23/3128; H01L 23/298; H01L 23/49816; H01L 23/49827

(57) ABSTRACT

An electronic package and the manufacturing method thereof are provided. The method includes forming a circuit structure on an encapsulating structure with a recess and a plurality of vias, disposing a plurality of conductive pillars in the plurality of vias to be electrically connected to the circuit structure, and disposing an electronic component in the recess to be electrically connected to the circuit structure. Afterwards, a routing structure is disposed on the encapsulating structure to be electrically connected to the plurality of conductive pillars and the electronic component. Therefore, by disposing the electronic component in the recess, the encapsulating structure covers the electronic component to facilitate dissipation of thermal stress.

### BACKGROUND

### 1. Technical Field

The present disclosure relates to a semiconductor device, and more particularly, to an electronic package and a manufacturing method thereof that can improve product yield.

### 2. Description of Related Art

With the vigorous development of portable electronic products in recent years, various related products are gradually moving towards a tendency of high density, high performance, and being light, thin, short, and small. Therefore, various package on package (POP) processes are thus rolled out, in order to meet the demands for products in light, thin, short, small and high density.

FIG. 1A to FIG. 1D are schematic cross-sectional views illustrating a manufacturing method of a conventional semiconductor package 1.

As shown in FIG. 1A, a circuit structure 10 is disposed on a carrier 9, and a plurality of conductive pillars 13 are formed on the circuit structure 10, and at least a semiconductor chip 11 is disposed on the circuit structure 10 through a die attached glue layer 18 with its non-active surface 11b, and the active surface 11a of the semiconductor chip 11 has a plurality of conductive bumps 12.

As shown in FIG. 1B, forming a package encapsulant 15 on the circuit structure 10, such that the package encapsulant 15 covers the semiconductor chip 11 and the conductive pillars 13. Then the surface of the package encapsulant 15 is flushed with the end surface of the conductive pillar 13 by a leveling process, such that the conductive pillar 13 be exposed from the surface of the package encapsulant 15.

As shown in FIG. 1C, forming a routing structure 16 on the package encapsulant 15, such that the routing structure 16 is electrically connected to the conductive pillars 13 and the plurality of conductive bumps 12, so that a plurality of conductive elements 17 such as C4 bump specification and other passive element 14 can be formed on the routing structure 16.

As shown in FIG. 1D, removing the carrier 9 to expose the circuit structure 10, then a plurality of solder balls 19 are formed on the circuit structure 10, such that the solder balls 19 are electrically connected to the circuit structure 10.

However, in the manufacturing method of the conventional semiconductor package 1, the mismatch between the coefficients of thermal expansion (CTE) of the package encapsulant 15 and the semiconductor chip 11 may easily cause the uneven thermal stress, easily cause the warpage of the package encapsulant 15, resulting in the crack of the semiconductor package 1 (especially the semiconductor chip 11), and the die attached glue layer 18 is prone to peeling, even the void may be generated in the package encapsulant 15 during the manufacturing process.

Moreover, in the manufacturing method of the conventional semiconductor package 1, the semiconductor chip 11 is disposed in the earlier processes, so the semiconductor chip 11 has to experience the high temperature processes of making the encapsulant 15, the routing structure 16 (such as RDL specification) and the conductive element 17 with C4 bump specification, etc., such that the semiconductor chip 11 may suffered from the thermal damage, such as thermal budget, and the damage may be accumulated and increased successively, thereby the damage may easily exceed what the semiconductor chip 11 could bear, resulting in the abnormality and even the destruction of the semiconductor chip 11, and further producing the reliability issue of products.

In addition, the conductive pillar 13 is directly manufactured on the circuit structure 10 by complicated processes such as exposure, development and electroplating, which is not conducive to reducing the manufacturing cost of the semiconductor package 1.

Therefore, how to overcome the above-mentioned problems of the prior art has become an urgent issue to be solved.

### SUMMARY

In view of the various shortcomings of the prior art, the present disclosure provides an electronic package, comprising: an encapsulating structure has a first surface and a second surface opposing to each other and provided with at least a recess and a plurality of vias connecting the first surface and the second surface, wherein a plurality of concaves connected to the first surface formed on a bottom surface of the recess, such that the recess connects the first surface and the second surface through the plurality of concaves; a circuit structure is disposed on the first surface of the encapsulating structure and exposed from the plurality of concaves and the plurality of vias; a plurality of conductive pillars are disposed in the plurality of vias and electrically connected to the circuit structure; an electronic component is disposed in the recess and electrically connected to the circuit structure; and a routing structure is disposed on the second surface of the encapsulating structure and electrically connected to the plurality of conductive pillars and/or the electronic component.

The present disclosure also provides a manufacturing method of an electronic package, comprising: providing an encapsulating structure having a first surface and second surface opposing to each other, wherein the second surface of the encapsulating structure has at least a recess; forming a circuit structure on the first surface of the encapsulating structure; forming a plurality of vias on the second surface of the encapsulating structure that connect the first surface and the second surface, and forming a plurality of concaves on a bottom surface of the recess; forming a plurality of conductive pillars in the plurality of vias that are connected to the circuit structure electrically, and disposing at least one electronic component in the recess, wherein the electronic component is electrically connected to the circuit structure; and forming a routing structure on the second surface of the encapsulating structure, wherein the routing structure is electrically connected to the plurality of conductive pillars.

In the aforementioned electronic package and the manufacturing method thereof, wherein the encapsulating structure is a plate body of semiconductor material.

In the aforementioned electronic package and the manufacturing method thereof, wherein an insulating material is filled between the electronic component and the recess. For example, the electronic component has an active surface and a non-active surface opposing to each other, and is electrically connected to the circuit structure through a plurality of conductive bumps with its active surface, wherein the plurality of conductive bumps are disposed in the plurality of concaves, and there is no colloid between the non-active surface and the routing structure. Furthermore, the non-active surface is in contact with the routing structure.

In the aforementioned electronic package and the manufacturing method thereof, wherein a plurality of conductive elements are formed on a surface of the circuit structure that is not in contact with the encapsulating structure.

It can be seen from the above, in the electronic package and the manufacturing method thereof of the present disclosure, it is mainly by the design of the encapsulating structure to have the electronic component disposed in the recess, such that the encapsulating structure covers the electronic component, thereby it can facilitate dissipation the thermal stress. Therefore, compared to the prior art, the present disclosure can not only prevent from the peeling of the conventional die attached glue layer and generation of void in the package encapsulant, but also the warpage of the encapsulating structure is not easy to occur, thereby preventing from the crack of the electronic package or electronic component.

Moreover, the manufacturing method of the present disclosure firstly makes the circuit structure and the conductive element, then disposes the electronic component, thus compared to the prior art, the present disclosure can avoid the electronic component to be damaged by the RDL process and the thermal budget produced by the conductive element during the manufacturing processes, so as to facilitate to improve the reliability of the manufacturing processes and products.

Furthermore, the manufacturing method of the present disclosure forms the via on the encapsulating structure by laser to make the conductive pillar, thus compared to the prior art, the manufacturing method of the present disclosure simplifies the manufacturing processes effectively, thereby facilitate to reduce the manufacturing cost of the electronic package.

### BRIEF DESCRIPTION OF THE DRAWINGS

FIG. 1A to FIG. 1D are schematic cross-sectional views illustrating the manufacturing method of a conventional semiconductor package.

FIG. 2A to FIG. 2E are schematic cross-sectional views illustrating the manufacturing method of an electronic package of the present disclosure.

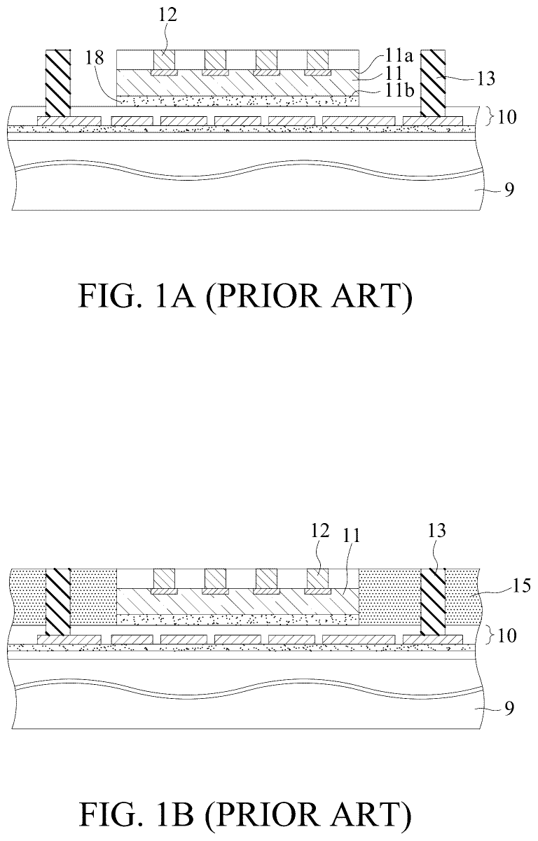

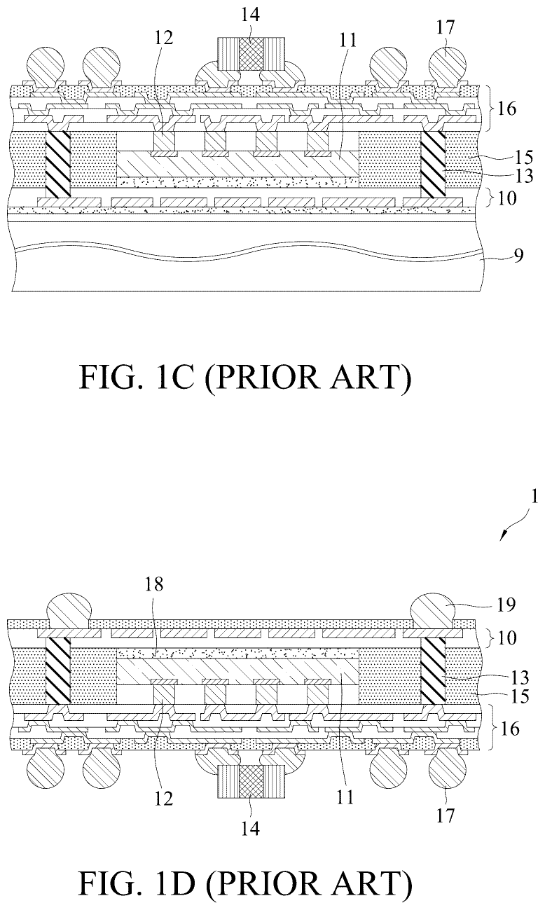

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

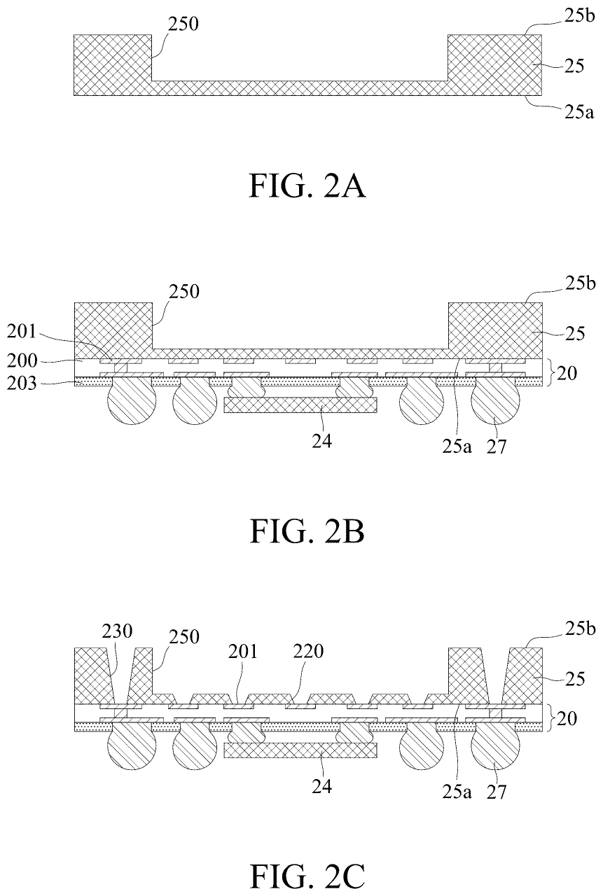

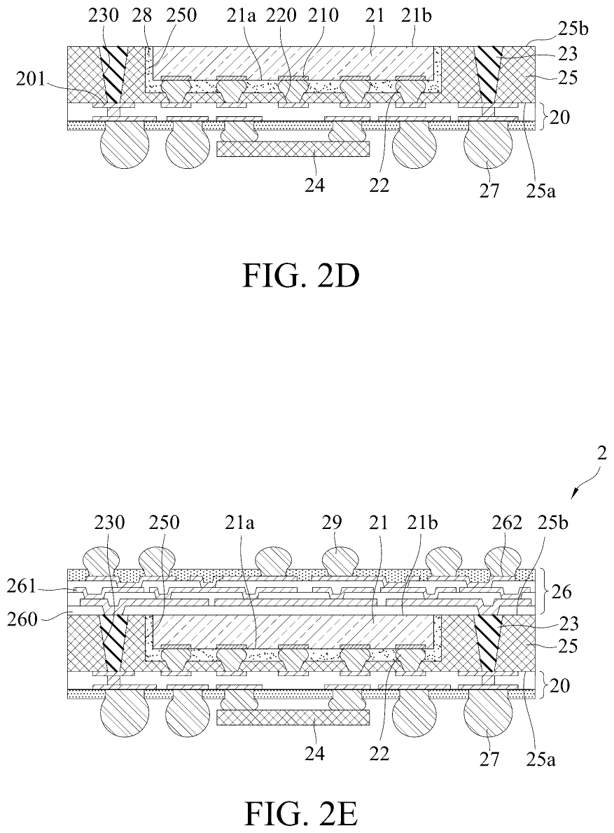

FIG. 2A to FIG. 2E are schematic cross-sectional views illustrating the manufacturing method of an electronic package 2 of the present disclosure.

As shown in FIG. 2A, providing an encapsulating structure 25 with a recess 250.

In this embodiment, the encapsulating structure 25 is, for example, a plate body of semiconductor material (such as silicon or glass), which has a first surface 25a and a second surface 25b opposing to each other, such that the recess 250 is formed on the second surface 25b. For example, the recess 250 can be formed by laser, etching or other methods, so that the recess 250 does not penetrate the encapsulating structure 25.

As shown in FIG. 2B, a circuit structure 20 is formed on the first surface 25a of the encapsulating structure 25.

In an embodiment, the circuit structure 20 is coreless, which includes a plurality of dielectric layer 200 and a circuit layer 201 disposed on the dielectric layer 200, such as of redistribution layer (RDL) specification. For example, the material for forming the circuit layer 201 is copper, and the material for forming the dielectric layer 200 is, for example, Polybenzoxazole (PBO), Polyimide (PI), Prepreg (PP) or other dielectric materials.

Moreover, a plurality of conductive elements 27 such as solder material, such as of C4 bump specification, for example, are formed on the outermost circuit layer 201 of the circuit structure 20. For example, an insulating protective layer 203 such as a solder mask layer can be formed on the dielectric layer 200, and a plurality of openings are formed on the insulating protective layer 203, such that the circuit layer 201 is exposed from the openings for being bonded to the conductive element 27.

In addition, at least one auxiliary functional element 24, such as a passive element, can be connected to the outermost circuit layer 201 of the circuit structure 20.

As shown in FIG. 2C, a plurality of vias 230 connecting the first surface 25a to the second surface 25b are formed on the second surface 25b of the encapsulating structure 25, and a plurality of concaves 220 are formed on the bottom surface of the recess 250.

In an embodiment, the concave 220 penetrates the encapsulating structure 25, such that the circuit layer 201 of the circuit structure 20 is exposed from the concave 220 and the via 230. For example, the concave 220 and the via 230 can be formed by laser, etching or other methods.

As shown in FIG. 2D, a plurality of conductive pillars 23 electrically connecting to the circuit layer 201 are formed on the circuit structure 20 exposed from the via 230, and at least one electronic component 21 is disposed in the recess 250 by placing a plurality of conductive bumps 22 into the concave 220, and electrically connected to the circuit structure 20.

The conductive pillar 23 is formed on the circuit layer 201 by electroplating to be electrically connected to the circuit layer 201. For example, the material for forming the conductive pillar 23 is a metal such as copper or solder material.

The electronic component 21 is an active element, a passive element or a combination thereof, etc., wherein the active element is a semiconductor chip, and the passive element is a resistor, capacitor or inductor.

In an embodiment, the electronic component 21 is a semiconductor chip, which has an active surface 21a and a non-active surface 21b opposing to each other, and is disposed on the circuit layer 201 exposed from the concave 220 and electrically connected to the circuit layer 201 with electrode pads 210 of its active surface 21a by a plurality of conductive bumps 22 such as copper pillars, solder balls, etc. in a flip-chip manner that the active surface 21a is face down.

Moreover, by arranging an insulating material 28 such as primer between the electronic component 21 and the recess 250 (including between the side surface of the electronic component 21 and the wall surface of the recess 250 and between the active surface 21a of the electronic component 21 and the bottom surface of the recess 250), so that the insulating material 28 covers the conductive bumps 22.

Furthermore, a leveling process can be performed. For example, part of the materials of the conductive pillar 23, the electronic component 21 and the encapsulating structure 25 can be removed by grinding, such that the end surface of the conductive pillar 23, the non-active surface 21b of the electronic component 21 and the second surface 25b of the encapsulating structure 25b are coplanar (or are flushed with each other).

As shown in FIG. 2E, forming a routing structure 26 on the second surface 25b of the encapsulating structure 25, so that the routing structure 26 is electrically connected to the conductive pillars 23.

In an embodiment, the routing structure 26 comprises a plurality of insulating layers 260, and a plurality of routing layers 261 disposed on the insulating layer 260, and the outermost insulating layer 260 may be served as a solder mask layer, such that a part of the outermost routing layer 261 is exposed from the solder mask layer for serving as an electrical contact pad 262, and a plurality of conductive members 29 (such as solder material), for disposing and connecting an electronic component (not shown) through the plurality of conductive members 29 subsequently. For example, the material for forming the routing layer 261 is copper, and the material for forming the insulating layer 260 is a dielectric material such as Polybenzoxazole (PBO), Polyimide (PI), Prepreg (PP) or others, etc.

In the subsequent processes, the electronic package 2 can be disposed on and connected to an electronic device (not shown) such as a circuit board through the conductive elements 27.

Therefore, the manufacturing method of the present disclosure is mainly by the design that makes a plate body of semiconductor material as the encapsulating structure 25 to dispose the electronic component 21 in the recess 250, such that the encapsulating structure 25 covers the electronic component 21. Since the coefficients of thermal expansion (CTE) for the encapsulating structure 25 and the electronic component 21 are matched with each other, so it further facilitate dissipation of thermal stress. Therefore, compared to the prior art, the manufacturing method of the present disclosure can not only avoid the peeling of the conventional die attached glue layer 18 and generation of void in the encapsulant 15 during performing the thermal processes, but also the encapsulating structure 25 is not prone to warping, thereby preventing the reliability issues such as crack of the electronic package 2 or electronic component 21, poor ball condition (i.e., the conductive element 27 falls and is electrically disconnected), non-wetting of the conductive element 27, or peeling of the circuit structure 20 (or the routing structure 26), etc., thereby can further improve the reliability issues of terminal electronic products (such as computers, mobile phones, etc.) of the electronic package.

Furthermore, the manufacturing method of the present disclosure firstly makes the circuit structure 20 and the conductive element 27 of C4 bump specification, then disposes the electronic component 21. Therefore, compared to the prior art (disposing the semiconductor chip 11 firstly, then making the routing structure 16 and the conductive element 17 of C4 bump specification), the present disclosure can avoid the damages of the electronic component 21 (or the semiconductor chip) made by the RDL process and the heat accumulation generated from the conductive element 27 during the manufacturing processes, to facilitate to improve the reliability of the manufacturing processes and products.

In addition, the manufacturing method of the present disclosure forms the via 230 on the encapsulating structure 25 by laser to manufacture the conductive pillar 23, thus compared to the conventional complicated processes such as exposure, development and electroplating, etc., the manufacturing method of the present disclosure can simplify the manufacturing processes effectively, thereby facilitate to reduce the manufacturing cost of the electronic package 2.

The present disclosure provides an electronic package 2, comprising: an encapsulating structure 25, an electronic component 21, a plurality of conductive pillars 23, a circuit structure 20 and a routing structure 26.

The encapsulating structure 25 has a first surface 25a and a second surface 25 opposing to each other, wherein a recess 250 and a plurality of vias 230 connecting the first surface 25a to the second surface 25b are disposed on the second surface 25b of the encapsulating structure 25, and a plurality of concaves 220 connecting to the first surface 25a are formed on the bottom surface of the recess 250, such that the recess 250 combines with the plurality of concaves 220 and connects the first surface 25a to the second surface 25b.

The circuit structure 20 is disposed on the first surface 25a of the encapsulating structure 25 and exposed from the plurality of concaves 220 and the plurality of vias 230.

The plurality of conductive pillars 23 are disposed in the plurality of vias 230 and electrically connected to the circuit structure 20.

The electronic component 21 is disposed in the recess 250 and electrically connected to the circuit structure 20.

The routing structure 26 is disposed on the second surface 25b of the encapsulating structure 25 and electrically connected to the plurality of conductive pillars 23 and/or the electronic component 21.

In an embodiment, the encapsulating structure 25 is a plate body of semiconductor material.

In an embodiment, the electronic component 21 is a semiconductor chip. For example, the electronic component 21 has an active surface 21a and a non-active surface 21b opposing to each other, and is electrically connected to the circuit structure 20 with its active surface 21a, so that there is no colloid between the non-active surface 21b and the routing structure 26. Further, the non-active surface 21b is in contact with the routing structure 26.

In an embodiment, a conductive element 27 is formed on a surface of the circuit structure 20 that is not in contact with the encapsulating structure 25.

In summary, the electronic package and the manufacturing method thereof of the present disclosure dispose the electronic component in the recess of the encapsulating structure by the design of the encapsulating structure, such that the encapsulating structure covers the electronic component, therefore facilitate dissipation thermal stress. As a result, not only the problems such as peeling of the conventional die attached layer and generation of void in the package encapsulant can be avoided during performing the thermal processes in the present disclosure, but also the encapsulating structure is not prone to warping, thereby can prevent from the crack of the electronic package or electronic component.

Furthermore, the manufacturing method of the present disclosure firstly makes the circuit structure and the conductive element, then disposes the electronic component, therefore the present disclosure can avoid the damages of the electronic component (or the semiconductor chip) made by the RDL process and the heat accumulation generated from the conductive element during the manufacturing processes, to facilitate to improve the reliability of the manufacturing processes and products.

In addition, the manufacturing method of the present disclosure forms the via on the encapsulating structure by laser to manufacture the conductive pillar, thus the manufacturing method of the present disclosure can simplify the manufacturing processes effectively, thereby facilitate to reduce the manufacturing cost of the electronic package.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
an encapsulating structure having a first surface and a second surface opposing to each other, and provided with a recess on the second surface and a plurality of vias connecting the first surface to the second surface, wherein a plurality of concaves connected to the first surface are formed on a bottom surface of the recess, such that the recess combines with the plurality of concaves to connect the first surface to the second surface;
a circuit structure disposed on the first surface of the encapsulating structure, and exposed from the plurality of concaves and the plurality of vias;
a plurality of conductive pillars disposed in the plurality of vias and electrically connected to the circuit structure;
an electronic component disposed in the recess and electrically connected to the circuit structure; and
a routing structure disposed on the second surface of the encapsulating structure and electrically connected to the plurality of conductive pillars and/or the electronic component.

2. The electronic package of claim 1, wherein the encapsulating structure is a plate body of semiconductor material.

3. The electronic package of claim 1, wherein an insulating material is filled between the electronic component and the recess.

4. The electronic package of claim 1, wherein the electronic component has an active surface and a non-active surface opposing to each other, and is electrically connected to the circuit structure through a plurality of conductive bumps with its active surface, wherein the plurality of conductive bumps are disposed in the plurality of concaves, and there is no colloid between the non-active surface and the routing structure.

5. The electronic package of claim 4, wherein the non-active surface is in contact with the routing structure.

6. The electronic package of claim 1, wherein a plurality of conductive elements are formed on a surface of the circuit structure that is not in contact with the encapsulating structure.

7. A manufacturing method of an electronic package, comprising:
providing an encapsulating structure having a first surface and second surface opposing to each other, wherein the second surface of the encapsulating structure has a recess;
forming a circuit structure on the first surface of the encapsulating structure;
forming a plurality of vias on the second surface of the encapsulating structure that connect the first surface to the second surface, and forming a plurality of concaves on a bottom surface of the recess;
forming a plurality of conductive pillars in the plurality of vias that are connected to the circuit structure electrically, and disposing an electronic component in the recess, wherein the electronic component is electrically connected to the circuit structure; and
forming a routing structure on the second surface of the encapsulating structure, wherein the routing structure is electrically connected to the plurality of conductive pillars.

8. The method of claim 7, wherein the encapsulating structure is a plate body of semiconductor material.

9. The method of claim 7, wherein an insulating material is filled between the electronic component and the recess.

10. The method of claim 7, wherein the electronic component has an active surface and a non-active surface opposing to each other, and is electrically connected to the circuit structure through a plurality of conductive bumps with its active surface, wherein the plurality of conductive bumps are disposed in the plurality of concaves, and there is no colloid between the non-active surface and the routing structure.

11. The method of claim 10, wherein the non-active surface is in contact with the routing structure.

12. The method of claim 7, wherein a plurality of conductive elements are formed on a surface of the circuit structure that is not in contact with the encapsulating structure.
